(19) United States
(12) Patent Application Publication
(10) Pub. No.: US 2019/0073050 A1
(43) Pub. Date: Mar. 7, 2019

(54) TOUCH SENSOR DEVICE

(71) Applicant: JAPAN AVIATION ELECTRONICS INDUSTRY, LIMITED, Tokyo (JP)

(72) Inventors: Akitoshi SAKAUE, Tokyo (JP); Mitsunori SATO, Tokyo (JP); Yutaka TAKEZAWA, Tokyo (JP); Kenji MATSUMOTO, Tokyo (JP); Mitsutoshi NAITO, Tokyo (JP)

(73) Assignee: JAPAN AVIATION ELECTRONICS INDUSTRY, LIMITED, Tokyo (JP)

(21) Appl. No.: 16/050,660

(22) Filed: Jul. 31, 2018

(30) Foreign Application Priority Data
Sep. 7, 2017 (JP) 2017-171821

(51) Int. Cl. G06F 3/041; G06F 3/0354; H05K 1/02

(52) U.S. Cl. CPC G06F 3/041; H05K 2201/10151; H05K 1/0296; G06F 3/03547

(57) ABSTRACT

In a touch sensor device comprising at least a printed wiring board with a wiring pattern made of cured conductive ink containing conductive particles formed on a transparent substrate, and a front cover having a plate surface parallel to the printed wiring board and configured with a transparent dielectric, one face of the front cover being a contact input surface, the whole of the wiring pattern formed in an area seen through the contact input surface on the substrate is formed on one face of the substrate on a side opposite to a side where the front cover is located.

### TECHNICAL FIELD

The present invention relates to a touch sensor device disposed on a display part, and more particularly to a touch sensor device in which a wiring pattern is print-formed using conductive ink.

### BACKGROUND ART

FIG. 1 shows a configuration of a film for touch panel described in Japanese Patent Application Laid-Open No. 2014-182619 (issued on Sep. 29, 2014; hereinafter referred to as Literature 1) as a conventional example of a touch sensor device of this kind. In this example, the film for touch panel is configured by superimposing a transparent electrode film 12 in which a pattern of a plurality of electrode wires 11 extending in an X direction are formed and a transparent electrode film 14 in which a pattern of a plurality of electrode wires 13 extending in an Y direction are formed.

Edges of the transparent electrode films 12 and 14 are provided with FPC boards 15 and 16, respectively. In FIG. 1, reference numerals 17 and 18 indicate electrode wires for output terminals and electrode wires for connection that are formed in the transparent electrode film 12 so as to perform output to the FPC board 15. Further, reference numerals 19 and 20 indicate electrode wires for output terminals and electrode wires for connection that are formed in the transparent electrode film 14 so as to perform output to the FPC board 16.

FIG. 2 shows a cross-sectional structure of the film for touch panel described in Literature 1, in which the transparent electrode films 12 and 14 are superimposed, and, furthermore, a front cover 21 is superimposed on a surface. In FIG. 2, reference numerals 22 and 23 indicate boards (substrates) of the transparent electrode films 12 and 14, and reference numerals 24 and 25 indicate adhesive.

In Literature 1, it is described that each of the electrode wires of the transparent electrode films 12 and 14 is formed by screen-printing and firing conductive paste ink (silver paste).

By the way, it is extremely advantageous to use a printing method to form a wiring pattern on a substrate as in the case of the film for touch panel described above, from viewpoints of productivity and manufacturing costs. Therefore, it is increasingly common to use a printing method using conductive ink containing conductive particles such as silver particles to form a wiring pattern on various kinds of touch sensor devices.

In the case of using a printing method to form a wiring pattern on a transparent substrate for a touch sensor device, for example, it is important to, in a sensor area located on a display part, prevent the wiring pattern from being visually recognized so that the wiring pattern does not decrease visibility quality of the display part. Therefore, in the sensor area, the wiring pattern is generally configured with thin wires or thin wire mesh that is difficult to visually recognize.

Further, in order to detect a contact input, the wiring pattern formed in the sensor area is conventionally print-formed on a face of the substrate on a side where the front cover is located in consideration of detection sensitivity like the configuration described in Literature 1 shown in FIG. 2. That is, the wiring pattern is print-formed on a front-side face of the substrate when seen from an operator performing a contact input operation.

In the configuration in which the wiring pattern is print-formed on the front-side face of the substrate when seen from the operator, however, the wiring pattern configured with thin wires or thin wire mesh so as not to be visually recognized is, strictly speaking, seen, or a phenomenon occurs that the wiring pattern has some visual effect of being visually recognized by the operator though the shape of the wiring is not clearly seen. It has been a problem in aiming at higher quality of a touch sensor device that a wiring pattern has such a visual effect as described above.

### SUMMARY OF THE INVENTION

An object of the present invention is to make it possible to significantly improve a phenomenon that a wiring pattern has a visual effect and provide a touch sensor device capable of realizing higher quality in comparison with a conventional touch sensor device.

According to a first aspect of the present invention, in a touch sensor device comprising at least a printed wiring board with a wiring pattern made of cured conductive ink containing conductive particles formed on a transparent substrate, and a front cover having a plate surface parallel to the printed wiring board and configured with a transparent dielectric, one face of the front cover being a contact input surface, it is assumed that the whole of the wiring pattern formed in an area seen through the contact input surface on the substrate is formed on one face of the substrate on a side opposite to a side where the front cover is located.

According to a second aspect of the present invention, in a touch sensor device comprising at least a printed wiring board with a wiring pattern made of cured conductive ink containing conductive particles formed on a transparent substrate, and a front cover having a plate surface parallel to the printed wiring board and configured with a transparent dielectric, one face of the front cover being a contact input surface, it is assumed that all of sensor electrodes receiving an input from the contact input surface, which are comprised in the wiring pattern, are formed on one face of the substrate on a side opposite to a side where the front cover is located.

According to a third aspect of the present invention, in a touch sensor device comprising at least a printed wiring board with a wiring pattern made of cured conductive ink containing conductive particles formed on a transparent substrate, and a front cover having a plate surface parallel to the printed wiring board and configured with a transparent dielectric, one face of the front cover being a contact input surface, it is assumed that, when two mutually non-parallel directions defined on the contact input surface are assumed to be an X direction and a Y direction, all of X-direction sensor electrodes detecting an X-direction position of an input from the contact input surface and Y-direction sensor electrodes detecting a Y-direction position of the input are formed on one face of the substrate on a side opposite to a side where the front cover is located.

According to a fourth aspect of the present invention, in a touch sensor device comprising at least a printed wiring board with a wiring pattern made of cured conductive ink containing conductive particles formed on a transparent substrate, and a front cover having a plate surface parallel to the printed wiring board and configured with a transparent dielectric, one face of the front cover being a contact input surface, it is assumed that the wiring pattern formed in an area seen through the contact input surface on the substrate comprises thin wire mesh, and all the thin wire mesh is formed on one face of the substrate on a side opposite to a side where the front cover is located.

According to a touch sensor device according to the present invention, since a wiring pattern is print-formed on one face of a substrate on a side opposite to a side where a front cover is located, a front cover side of the wiring pattern that is visually recognized by an operator performing a contact input operation is a smooth plane defined by one face (a back-side face) of the substrate. Therefore, diffuse reflection does not easily occur, and a visual effect by diffuse reflection of the wiring pattern disappears. Thus, it is possible to provide a high-quality touch sensor device capable of improving visibility of a display part.

### BRIEF DESCRIPTION OF THE DRAWINGS

FIG. 1 is an exploded perspective view showing an example of a conventional configuration of a touch sensor device;

FIG. 2 is a diagram showing a cross-sectional structure of the touch sensor device shown in FIG. 1;

FIG. 3A is a diagram for illustrating a light reflection state in the case of the conventional configuration in which a wiring pattern is print-formed on a front-side face of a substrate;

FIG. 3B is a diagram for illustrating a light reflection state in the case of a configuration of the present invention in which a wiring pattern is print-formed on a back-side face of a substrate;

FIG. 4A is a perspective view showing an outline of a configuration and arrangement of a touch sensor device;

FIG. 4B is a diagram for illustrating a cross-sectional structure in a case where a touch sensor device according to the present invention is a touch panel;

FIG. 5 is a plan view showing a configuration example of the touch panel;

FIG. 6A is a partially enlarged diagram showing details of Y-direction sensor electrodes of the touch panel shown in FIG. 5;

FIG. 6B is a partially enlarged diagram showing details of X-direction sensor electrodes of the touch panel shown in FIG. 5; and

FIG. 7 is a plan view showing another configuration example of the touch panel.

### DETAILED DESCRIPTION OF THE EMBODIMENT

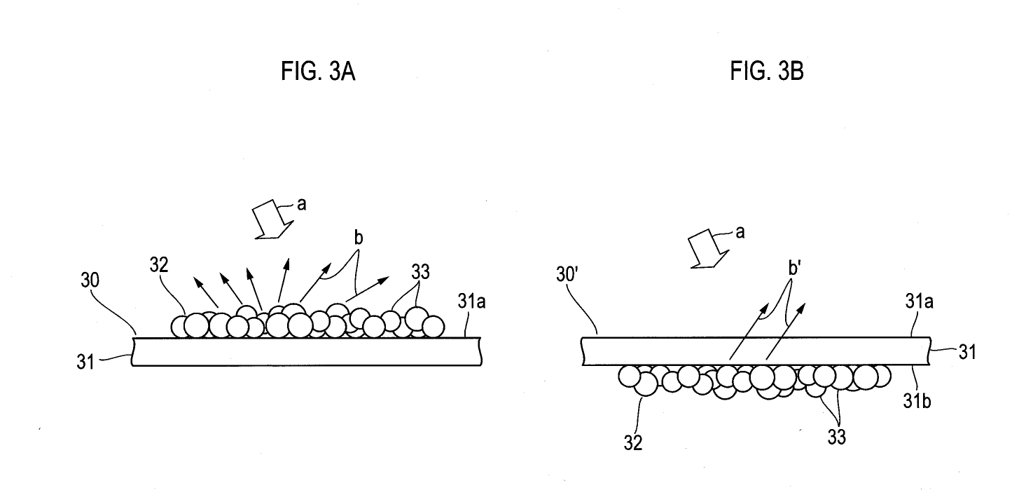

First, with reference to FIG. 3A, description will be made on a phenomenon that, in a touch sensor device comprising at least a printed wiring board with a wiring pattern made of cured conductive ink containing conductive particles formed on a transparent substrate, and a front cover having a plate surface parallel to the printed wiring board and configured with a transparent dielectric, one face of the front cover being a contact input surface, the wiring pattern configured with thin wires or thin wire mesh is seen in a conventional configuration in which the wiring pattern is formed on a face of the substrate on a side where the front cover is located, that is, the wiring pattern is formed on a front-side face of the substrate when seen from an operator performing a contact input operation.

In FIG. 3A, reference numeral 31 indicates a substrate of a printed wiring board 30, and reference numeral 32 indicates a wiring pattern configured with thin wires. Further, reference numeral 33 indicates conductive particles constituting the wiring pattern 32. The wiring pattern 32 is formed on a front-side face 31a of the substrate 31. A front cover is not shown.

On a surface of the wiring pattern 32 formed by printing and curing conductive ink, unevenness is formed due to an external form of the conductive particles 33 as shown in FIG. 3A. An arrow a indicates an incident direction of external light incident from a front cover side, and the external light is diffusely reflected by the unevenness existing on the surface of the wiring pattern 32 as indicated by arrows b. This diffuse reflection causes an area where the wiring pattern 32 exists to be seen whitish and dim. Moreover, it is seen from any angle.

For example, in a case where the conductive particles 33 are silver particles, the wiring pattern 32 having metallic luster is not seen, but the area where the wiring pattern 32 exists is seen dim and whitish instead. In a case where the conductive particles are carbon particles that are originally black also, a similar phenomenon occurs. It influences visibility of a display part located behind the touch sensor device that the area where the wiring pattern 32 exists is seen whitish as described above, and visibility quality of the display part is decreased.

Next, description will be made on a configuration adopted by the present invention that significantly improves the phenomenon that the wiring pattern 32 is seen as described above and improves the visibility quality of the display part with reference to FIG. 3B.

As shown in FIG. 3B, it is assumed in the present invention that the wiring pattern 32 on a printed wiring board 30′ is formed on a back-side surface 31b of the substrate 31, that is, the wiring pattern 32 is formed on a face of the substrate 31 on a side opposite to a side where the front cover is located.

By forming the wiring pattern 32 as described above, the front cover side of the wiring pattern 32 that is visually recognized by the operator is defined by the back-side surface 31b of the substrate 31 and is a smooth plane with an extremely little unevenness. Therefore, diffuse reflection is significantly reduced. On the back-side surface 31b, though a little amount of diffuse reflection occurs because a completely smooth surface of reflection is not formed by the conductive particles 33, but almost all of its visual effect disappears. Even if slight reflection close to specular reflection as indicated by an arrow b′ occurs on the back-side surface 31b, the reflection is seen only from a particular angle that accurately corresponds to the direction of reflected light indicated by the arrow b′, and influence on the visibility quality of the display part is extremely limited or can be ignored. Since the unevenness of the surface of the wiring pattern 32 due to the external form of the conductive particles 33 exists on the back side of the wiring pattern 32 when seen from the operator, it does not form a surface of reflection of external light and is not visually recognized by the operator.

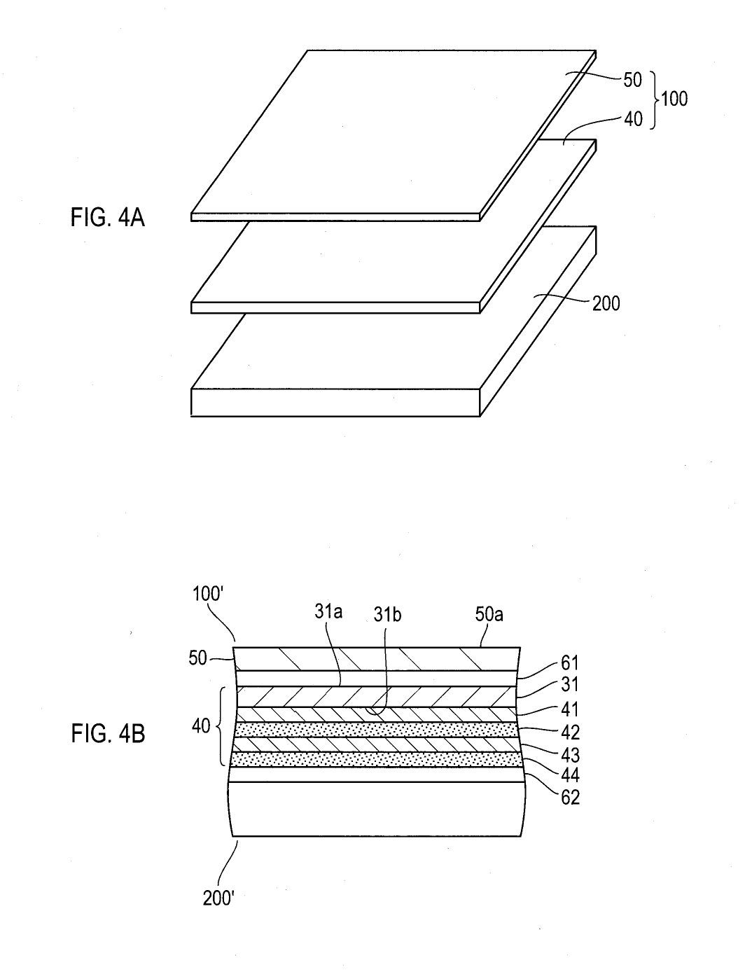

FIG. 4A shows an outline of a configuration and arrangement of the touch sensor device according to the present invention. A touch sensor device 100 is configured comprising a printed wiring board 40 and a front cover 50. In FIG. 4A, reference numeral 200 indicates a display part.

FIG. 4B shows a layer configuration of the printed wiring board 40 in a case where the touch sensor device 100 shown in FIG. 4A is a touch panel 100′ that detects a contact input position, and the display part 200 is a liquid crystal display device 200′, and an outline of a cross-section structure in a state where the touch panel 100′ is configured by the printed wiring board 40 and the front cover 50 being joined, and, furthermore, the touch panel 100′ is joined to and disposed on the liquid crystal display device 200′.

In this example, the printed wiring board 40 has a configuration in which a first wiring layer 41, an insulating layer 42, a second wiring layer 43 and a protective film 44 are formed and laminated in order on the back-side surface 31b of the substrate 31 as shown in FIG. 4B. In this example, the wiring pattern made of cured conductive ink containing conductive particles is formed by the two wiring layers 41 and 43.

The front cover 50 is attached to the front-side face 31a of the substrate 31 of the printed wiring board 40, and OCA (optical clear adhesive) 61 is used for the attachment. An upper surface (an outside surface) of the front cover 50 is a contact input surface 50a.

The liquid crystal display device 200′ is disposed on the printed wiring board 40 side of the touch panel 100′ being attached with OCA 62.

In the touch panel 100′ in the configuration as described above, all of the substrate 31, the front cover 50, the insulating layer 42 and the protective film 44 are formed with transparent material. For example, PET (polyethylene terephthalate) or PC (polycarbonate) is used for the substrate 31, and, for example, PC is used for the front cover 50. Acrylic resin or epoxy resin is used for the insulating layer 42 and the protective film 44. In this example, conductive ink containing silver particles is used as the conductive ink forming the wiring pattern (the wiring layers 41 and 43). A particle diameter of the silver particles is selected, for example, within a range from 0.1 μm to 3.0 μm.

Next, description will be made on a specific configuration of the touch panel 100′ having the cross-sectional structure as shown in FIG. 4B.

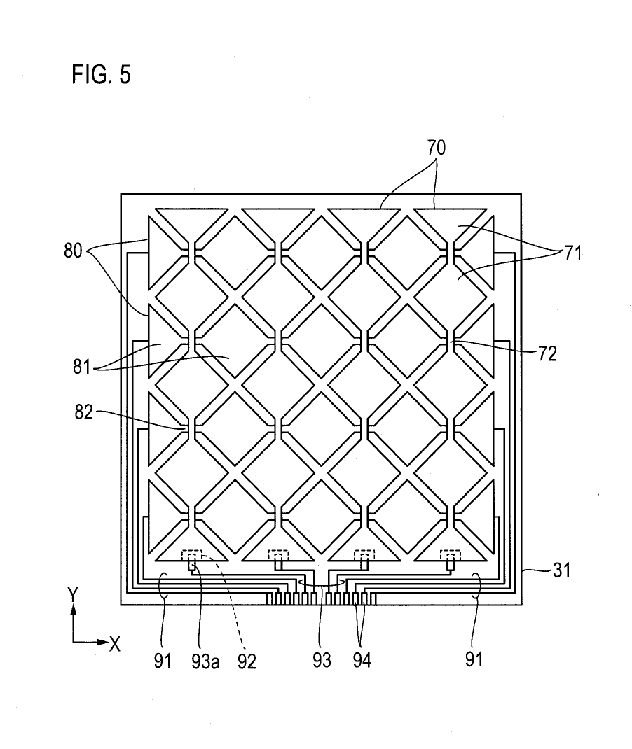

FIG. 5 shows a configuration example of the touch panel 100′. Sensor electrodes that receive an input from the contact input surface 50a of the front cover 50 are configured with a wiring pattern. The sensor electrodes comprise a plurality of X-direction sensor electrodes 70 that detect an X-direction position of an input and a plurality of Y-direction sensor electrodes 80 that detect a Y-direction position of the input.

The Y-direction sensor electrodes 80 comprise a plurality of island-shaped electrodes 81 arrayed in the X direction parallel to a side of the square substrate 31 and coupling parts 82 each of which couples adjoining island-shaped electrodes 81 and are formed by the first wiring layer 41. The plurality of Y-direction sensor electrodes 80 are provided being arranged in parallel in the Y direction parallel to another side adjoining the one side of the substrate 31.

The X-direction sensor electrodes 70 are formed by the second wiring layer 43 that is insulated from the first wiring layer 41 by the insulating layer 42 and comprise a plurality of island-shaped electrodes 71 arrayed in the Y direction and coupling parts 72 each of which couples adjoining island-shaped electrodes 71. The plurality of X-direction sensor electrodes 70 are provided being arranged in parallel in the X direction.

The X-direction sensor electrodes 70 and the Y-direction sensor electrodes 80 cross in a state of being mutually insulated, and the coupling parts 72 and 82 are located at positions where they mutually overlap.

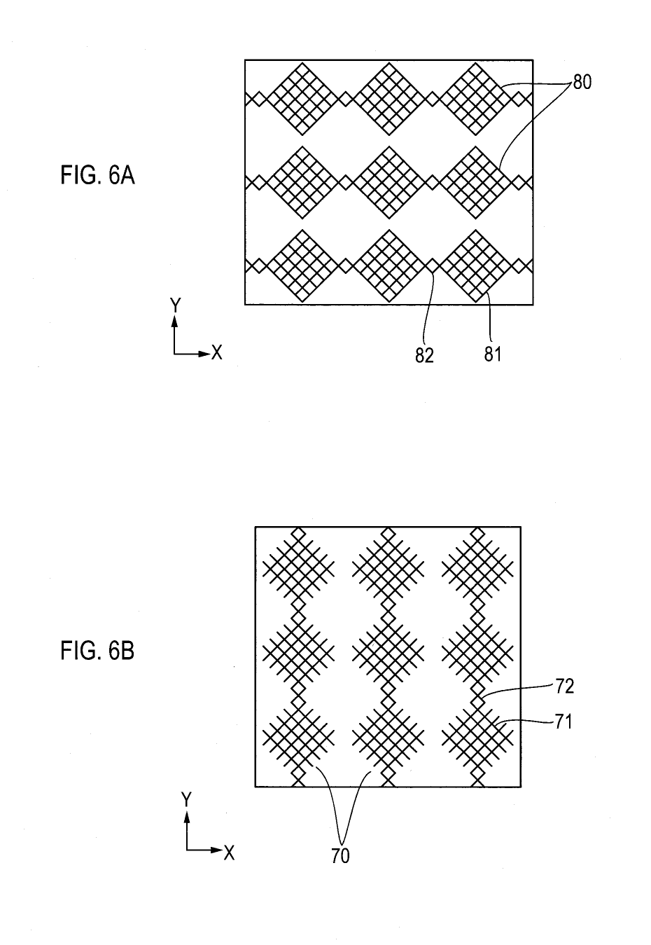

Lead-out wires 91 are connected to both of X-direction ends of each Y-direction sensor electrode 80, and one Y-direction end of each X-direction sensor electrode 70 is connected to a connection part 93a formed on one end of a lead-out wire 93, via a through hole 92 formed in the insulating layer 42. Terminals 94 are formed in an array on a middle part of one side of the substrate 31, and the lead-out wires 91 and 93 extend to the terminals 94 and connected to the terminals 94, respectively. The lead-out wires 91 and 93, the connection part 93a and the terminals 94 are formed by the first wiring layer 41. Each of the Y-direction sensor electrodes 80 and the X-direction sensor electrodes 70 is formed with thin wire mesh as shown in FIGS. 6A and 6B, and each of the connection parts 93a of the lead-out wires 93 and the terminals 94 is also formed with thin wire mesh though it is not shown in detail in FIG. 5.

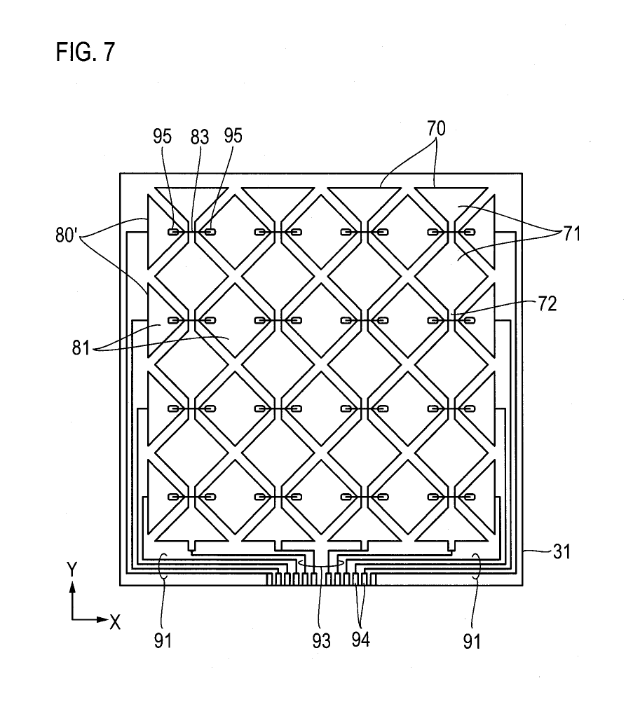

FIG. 7 shows another configuration example of the touch panel. The touch panel is different from the touch panel shown in FIG. 5 in the way of forming sensor electrodes. In this example, the X-direction sensor electrodes 70, the lead-out wires 91 and 93, the terminals 94 and the island-shaped electrodes 81 of Y-direction sensor electrodes 80′ are formed by the first wiring layer 41.

Adjoining island-shaped electrodes 81 of the Y-direction sensor electrodes 80′ are coupled with a jumper wire 83 formed by the second wiring layer 43. Both ends of the jumper wire 83 are connected to island-shaped electrodes 81 via through holes 95 provided in the insulating layer 42, respectively. The jumper wires 83 and the coupling parts 72 are located at positions where they mutually overlap. Each of the X-direction sensor electrodes 70, the island-shaped electrodes 81 of the Y-direction sensor electrodes 80′ and the terminals 94 is formed with thin wire mesh similarly to the touch panel shown in FIG. 5, and each jumper wire 83 is formed with a thin wire though it is not shown in detail in FIG. 7.

Though the two X and Y directions are two directions orthogonal to each other in touch panel described above, the two X and Y directions defined on the contact input surface 50a so that a contact input position can be detected on the touch panel does not necessarily have to be orthogonal to each other. The two directions only have to be mutually non-parallel.

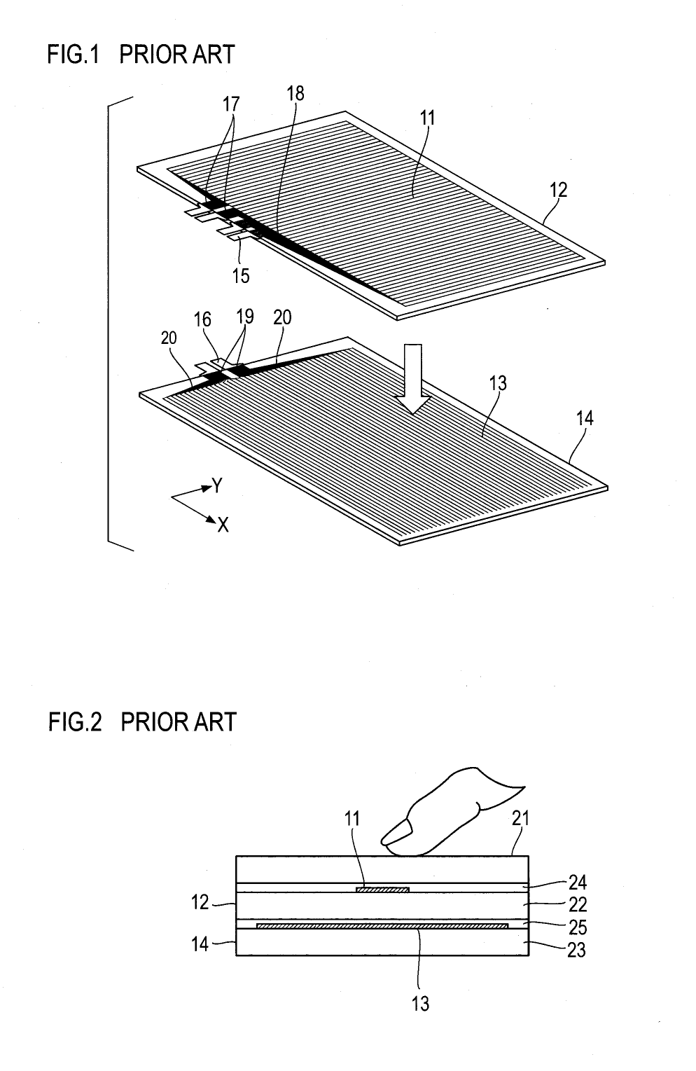

Description has been made on a touch panel that detects an input position in two X and Y directions as a specific example of a touch sensor device according to the present invention. However, the touch sensor device may be, for example, in a configuration in which an input position in one direction is detected or in a configuration in which an input is merely detected. Furthermore, the touch sensor device is not limited to such that comprises one printed wiring board but may be, for example, such that comprises a plurality of printed wiring boards like the conventional configuration example shown in FIGS. 1 and 2.

The present invention is characterized in that a print-formed wiring pattern is formed on one face of a substrate on a side opposite to a side where a front cover is located. To form sensor electrodes that receive an input from a contact input surface in this manner can be said to be disadvantageous from a viewpoint of detection sensitivity, but this problem can be sufficiently coped with by correction on a detection circuit side.

Further, the present invention is not limited to the configuration in which the whole wiring pattern to be print-formed exists on one face of a substrate on a side opposite to a side where a front cover is located. Such a wiring pattern that does not influence visibility of a display part may be formed on the other face on a side that is the side where the front cover is located. In other words, if such a wiring pattern that influences visibility of the display part is caused to face the back of a contact input surface, that is, if the wiring pattern is caused to exist on one face of the substrate on the side opposite to the side where the front cover is located, the object of the present invention can be achieved.

The above-stated wiring pattern that influences visibility of the display part may be (1) the whole of a wiring pattern formed in an area on a substrate that is seen through a contact input surface. Otherwise, (2) the wiring pattern may all sensor electrodes that receive an input from a contact input surface. Otherwise, (3) the wiring pattern may be X-direction sensor electrodes and Y-direction sensor electrodes. Otherwise, (4) the wiring pattern may be all of thin wire mesh formed in the area on the substrate that is seen through the contact input surface.

What is claimed is:

1. A touch sensor device comprising at least a printed wiring board with a wiring pattern made of cured conductive ink containing conductive particles formed on a transparent substrate, and a front cover having a plate surface parallel to the printed wiring board and configured with a transparent dielectric, one face of the front cover being a contact input surface, wherein
the whole of the wiring pattern formed in an area seen through the contact input surface on the substrate is formed on one face of the substrate on a side opposite to a side where the front cover is located.

2. A touch sensor device comprising at least a printed wiring board with a wiring pattern made of cured conductive ink containing conductive particles formed on a transparent substrate, and a front cover having a plate surface parallel to the printed wiring board and configured with a transparent dielectric, one face of the front cover being a contact input surface, wherein
all of sensor electrodes receiving an input from the contact input surface, which are comprised in the wiring pattern, are formed on one face of the substrate on a side opposite to a side where the front cover is located.

3. A touch sensor device comprising at least a printed wiring board with a wiring pattern made of cured conductive ink containing conductive particles formed on a transparent substrate, and a front cover having a plate surface parallel to the printed wiring board and configured with a transparent dielectric, one face of the front cover being a contact input surface, wherein
when two mutually non-parallel directions defined on the contact input surface are assumed to be an X direction and a Y direction, all of X-direction sensor electrodes detecting an X-direction position of an input from the contact input surface and Y-direction sensor electrodes detecting a Y-direction position of the input are formed on one face of the substrate on a side opposite to a side where the front cover is located.

4. A touch sensor device comprising at least a printed wiring board with a wiring pattern made of cured conductive ink containing conductive particles formed on a transparent substrate, and a front cover having a plate surface parallel to the printed wiring board and configured with a transparent dielectric, one face of the front cover being a contact input surface, wherein
the wiring pattern formed in an area seen through the contact input surface on the substrate comprises thin wire mesh, and all the thin wire mesh is formed on one face of the substrate on a side opposite to a side where the front cover is located.

5. The touch sensor device according to claim 1, wherein the wiring pattern formed on the one face of the substrate on the side opposite to the side where the front cover is located is formed comprising a plurality of wiring layers superimposed on the one face side of the same substrate.

6. The touch sensor device according to claim 2, wherein the wiring pattern formed on the one face of the substrate on the side opposite to the side where the front cover is located is formed comprising a plurality of wiring layers superimposed on the one face side of the same substrate.

7. The touch sensor device according to claim 3, wherein the wiring pattern formed on the one face of the substrate on the side opposite to the side where the front cover is located is formed comprising a plurality of wiring layers superimposed on the one face side of the same substrate.

8. The touch sensor device according to claim 4, wherein the wiring pattern formed on the one face of the substrate on the side opposite to the side where the front cover is located is formed comprising a plurality of wiring layers superimposed on the one face side of the same substrate.

9. The touch sensor device according to claim 1, wherein the wiring pattern formed on the one face of the substrate on the side opposite to the side where the front cover is located is formed on the one face side of each of a plurality of substrates.

10. The touch sensor device according to claim 2, wherein the wiring pattern formed on the one face of the substrate on the side opposite to the side where the front cover is located is formed on the one face side of each of a plurality of substrates.

11. The touch sensor device according to claim 3, wherein the wiring pattern formed on the one face of the substrate on the side opposite to the side where the front cover is located is formed on the one face side of each of a plurality of substrates.

12. The touch sensor device according to claim 4, wherein the wiring pattern formed on the one face of the substrate on the side opposite to the side where the front cover is located is formed on the one face side of each of a plurality of substrates.
